(19) United States
(12) Patent Application Publication
(10) Pub. No.: US 2024/0349560 A1
(43) Pub. Date: Oct. 17, 2024

(54) LIGHT EMITTING DISPLAY DEVICE

(71) Applicant: Samsung Display Co., LTD., Yongin-si (KR)

(72) Inventors: JEONGHYUN LEE, Yongin-si (KR); Pil Gyu KANG, Yongin-si (KR); Young Hoon YOO, Yongin-si (KR); EUNA YU, Yongin-si (KR); HANUL LEE, Yongin-si (KR); SANGCHEON HAN, Yongin-si (KR)

(73) Assignee: Samsung Display Co., LTD., Yongin-si (KR)

(21) Appl. No.: 18/432,756

(22) Filed: Feb. 5, 2024

(30) Foreign Application Priority Data
Apr. 11, 2023 (KR) 10-2023-0047537

(51) Int. Cl. H10K 59/131; H10K 59/121

(52) U.S. Cl. CPC H10K 59/1315; H10K 59/1213

(57) ABSTRACT

A light emitting display device includes a substrate, a first conductive layer disposed on the substrate, a first insulating layer covering the first conductive layer, a semiconductor layer disposed on the first insulating layer, a second insulating layer disposed on the semiconductor layer, a second conductive layer disposed on the second insulating layer, and a data pad electrode disposed in an outer side of a display area. The first conductive layer is formed as a triple layer including a lower layer, an intermediate layer, and an upper layer. The data pad electrode and the first conductive layer are formed as the same triple layer, the lower layer of the triple layer includes titanium, the intermediate layer of the triple layer includes copper, and the upper layer of the triple layer includes an alloy of molybdenum and titanium.

### CROSS-REFERENCE TO RELATED APPLICATION(S)

This application claims priority to and benefits of Korean Patent Application No. 10-2023-0047537 under 35 U.S.C. § 119, filed on Apr. 11, 2023, in the Korean Intellectual Property Office, the entire contents of which are incorporated herein by reference.

### BACKGROUND

### 1. Technical Field

Embodiments relate to a light emitting display device.

### 2. Description of the Related Art

A display device is a device that displays a screen, and includes a liquid crystal display (LCD), an organic light emitting diode (OLED) display, and the like. Such display devices are used in various electronic devices such as mobile phones, navigation devices, digital cameras, electronic books, portable game consoles, and various terminals.

The OLED display has self-luminance characteristics and, unlike the liquid crystal display, does not require a separate light source, so the thickness and weight may be reduced. The OLED display has high quality characteristics such as low power consumption, high luminance, and fast response speed.

### SUMMARY

Embodiments provide a light emitting display device capable of preventing an increase in resistance during a process, and of reducing electric power consumption.

However, embodiments of the disclosure are not limited to those set forth herein. The above and other embodiments will become more apparent to one of ordinary skill in the art to which the disclosure pertains by referencing the detailed description of the disclosure given below.

In an embodiment, a light emitting display device may include a substrate, a first conductive layer disposed on the substrate, a first insulating layer covering the first conductive layer, a semiconductor layer disposed on the first insulating layer, a second insulating layer disposed on the semiconductor layer, a second conductive layer disposed on the second insulating layer, and a data pad electrode disposed in an outer side of a display area. The first conductive layer may be formed as a triple layer including a lower layer, an intermediate layer, and an upper layer, The data pad electrode and the first conductive layer may be formed as the same triple layer structure, the lower layer of the triple layer may include titanium, the intermediate layer of the triple layer may include copper, and the upper layer of the triple layer may include an alloy of molybdenum and titanium.

The data pad electrode and the first conductive layer may be etched by two wet etching processes.

The second conductive layer may be etched by a wet etching process.

The second insulating layer and the semiconductor layer may be etched by a dry etching process after the wet etching process.

The first insulating layer may also be etched by the dry etching process.

The first conductive layer may include a lower storage electrode, a data line, and a first driving voltage line, the semiconductor layer may include a first semiconductor, a second semiconductor, and a third semiconductor, and the second conductive layer may include a first gate electrode, a first scan signal line, a second scan signal line, and a driving voltage line connection portion.

An opening overlapping the first semiconductor may be disposed in the second insulating layer, a first part of the opening does not overlap the second conductive layer in a plan view, and a second part of the opening may overlap the second conductive layer in a plan view, and in the first semiconductor, the opening may be formed by etching a portion of the opening exposed by the first part of the opening by the dry etching process.

The second conductive layer overlapping the opening in a plan view may be the driving voltage line connection portion.

The second insulating layer may protrude from a periphery of the opening to an outer side of the driving voltage line connection portion in a plan view.

A boundary portion disposed toward the driving voltage line connection portion among boundary portions of the opening of the first semiconductor may protrude from the driving voltage line connection portion in a plan view.

The second conductive layer may be formed as a double layer including a lower layer and an upper layer.

The lower layer of the double layer may include titanium, and the upper layer of the double layer may include copper.

A light emitting display device further include an organic insulating layer covering the second conductive layer, an anode disposed on the organic insulating layer, and a pixel defining layer including an opening that exposes a portion of the anode.

The second conductive layer may further include a connection electrode electrically connected to the first semiconductor, the third semiconductor, and the lower storage electrode, and the connection electrode may be electrically connected to the anode through the opening disposed on the organic insulating layer.

The data pad electrode may be disposed on the substrate, and the organic insulating layer may be disposed on the data pad electrode, and may include an opening exposing a portion of the data pad electrode.

The semiconductor layer may include an oxide semiconductor.

In an embodiment, a light emitting display device may include a substrate, a first conductive layer disposed on the substrate, a first insulating layer covering the first conductive layer, a semiconductor layer disposed on the first insulating layer, a second insulating layer disposed on the semiconductor layer, a second conductive layer disposed on the second insulating layer, and a data pad electrode disposed in an outer side of a display area. The second conductive layer may be formed as a triple layer including a lower layer, an intermediate layer, and an upper layer, the data pad electrode and the second conductive layer may be formed as the same triple layer. The lower layer of the triple layer may include titanium (Ti), the intermediate layer of the triple layer may include copper (Cu), and the upper layer of the triple layer may include Indium tin oxide (ITO) that is a transparent conductive material, and the data pad electrode and the second conductive layer may be formed by a wet etching process.

A light emitting display device may further include an organic insulating layer covering the second conductive layer, wherein the data pad electrode may be disposed on the substrate, the first insulating layer, and the second insulating layer and the organic insulating layer may include an opening disposed on the data pad electrode and exposing a portion of the data pad electrode.

The second insulating layer and the semiconductor layer may be etched by a dry etching process after the wet etching process.

The first conductive layer may be formed as a double layer including a lower layer and an upper layer, and the lower layer of the double layer may include titanium, and the upper layer of the double layer may include copper.

According to embodiments, since the gate conductive layer is not formed by two-step wet etching process, resistance may not be increased by narrowing the width of the gate conductive layer, and thus resistance may be prevented from being increased during the process. Since the resistance does not increase, power consumption may also be reduced.

### BRIEF DESCRIPTION OF THE DRAWINGS

FIG. 1 is a schematic diagram of an equivalent circuit of a pixel of a light emitting display device according to an embodiment.

FIGS. 2, 3, 4, 5, 6, 7, and 8 are schematic plan views showing a pixel of a light emitting display device according to an embodiment according to manufacturing sequence.

FIG. 9 is a schematic cross-sectional view of a pixel of a light emitting display device according to an embodiment.

FIG. 10 is a schematic cross-sectional view of a data pad portion of a light emitting display device according to an embodiment.

FIGS. 11A, 11B, 12A, 12B, 13A, 13B, 14A, 14B, 15A, and 15B sequentially show a method of manufacturing a gate conductive layer according to an embodiment.

FIGS. 16, 17, and 18 show a structure of a portion of a pixel according to an embodiment.

FIGS. 19A, 19B, 20A, 20B, 21A, 21B, 22, 23A, 23B, 24A, and 24B sequentially show a method of manufacturing a gate conductive layer according to a Comparative Example.

FIG. 25 shows a structure of a portion of a pixel according to a Comparative Example.

FIG. 26 is an enlarged photographed view of a portion of a pixel according to an exemplary embodiment.

FIG. 27 is a schematic cross-sectional view of a data pad portion of a light emitting display device according to an embodiment.

FIG. 28 shows a method of manufacturing a portion of a light emitting display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

For example, throughout the specification, when it is said that an element such as a wire, layer, film, region, area, substrate, plate, or constituent element “is extended (or extends) in a first direction or second direction”, this does not mean only a straight shape extending straight in the corresponding direction, but may mean a structure that substantially extends in the first direction or the second direction, is partially bent, has a zigzag structure, or extends with having a curved structure.

For example, an electronic device (for example, a mobile phone, a TV, a monitor, a laptop computer, or the like) included in a display device, a display panel, or the like described in the specification, or an electronic device included in a display device, a display panel, or the like manufactured by a manufacturing method described in the specification is not excluded from the scope of the specification.

Hereinafter, a light emitting display device according to an embodiment is discussed in detail with reference to the drawings.

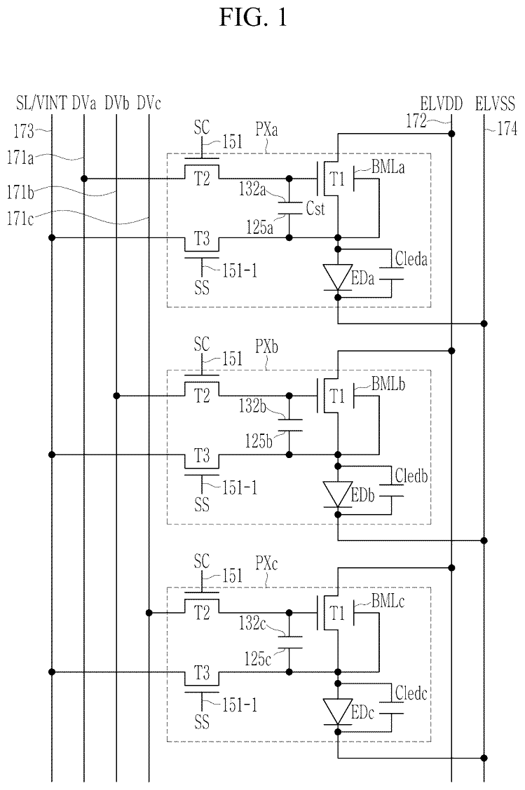

FIG. 1 is a schematic diagram of an equivalent circuit of a pixel of a light emitting display device according to an embodiment.

FIG. 1 shows a circuit diagram of three pixels PXa, PXb, and PXc including a group of light emitting diodes EDa, EDb, and EDc.

Pixels may include a first pixel PXa, a second pixel PXb, and a third pixel PXc.

Each of the first pixel PXa, the second pixel PXb, and the third pixel PXc may include transistors T1, T2, and T3, a storage capacitor Cst and the light emitting diodes EDa, EDb, and EDc as light emitting elements. For example, each pixel PXa, PXb, and PXc may be divided into the light emitting diodes EDa, EDb, and EDc and a pixel circuit portion, the pixel circuit portion may include the transistors T1, T2, and T3 and the storage capacitor Cst in FIG. 1. For example, according to an embodiment, it may further include capacitors Cleda, Cledb, and Cledc (hereinafter, referred to as a light emitting capacitor) connected to end portions (e.g., opposite portions) of the light emitting diodes EDa, EDb, and EDc, and the light emitting capacitors Cleda, Cledb, and Cledc may not be included in the pixel circuit portion but included in the light emitting diodes EDa, EDb, and EDc.

The transistors T1, T2, and T3 may be formed as a driving transistor T1 (also referred to as a first transistor) and two switching transistors T2 and T3, and the two switching transistors may be divided into an input transistor T2 (also referred to as a second transistor) and an initializing transistor T3 (also referred to as a third transistor). Each of transistors T1, T2, and T3 may include a gate electrode, a first electrode, and a second electrode, and also may include a semiconductor layer including a channel such that the current may flow or may be blocked through/by the channel of the semiconductor layer according to the voltage of the gate electrode. For example, according to voltages applied to respective transistors T1, T2, and T3, one of the first electrode and the second electrode may be a source electrode and the other thereof may be a drain electrode.

The gate electrode of the driving transistor T1 may be connected to first end portions 132a, 132b, and 132c of the storage capacitor Cst, and also connected to the second electrode (as an output electrode) of the input transistor T2. For example, a first electrode of the driving transistor T1 may be connected to a driving voltage line 172 transferring driving voltage ELVDD, and a second electrode of the driving transistor T1 may be connected to anodes of the light emitting diodes EDa, EDb, and EDc, second end portions 125a, 125b, and 125c of the storage capacitor Cst, a first electrode of the initializing transistor T3, overlapping electrodes BMLa, BMLb, and BMLc, and first end portions of the light emitting capacitors Cleda, Cledb, and Cledc. The driving transistor T1 may receive data voltages DVa, DVb, and DVc through the gate electrode according to a switching operation of the input transistor T2, and may supply the driving current to the light emitting diodes EDa, EDb, and EDc according to the voltage of the gate electrode. For example, the storage capacitor Cst may store and maintains the voltage of the gate electrode of the driving transistor T1. For example, the overlapping electrodes BMLa, BMLb, and BMLc may overlap a channel of the semiconductor layer included in the driving transistor T1 to supplement characteristics of the channel of the driving transistor T1.

The gate electrode of the input transistor T2 may be connected to a first scan signal line 151 transferring a first scan signal SC. A first electrode of the input transistor T2 may be connected to data lines 171a, 171b, and 171c transferring data voltages DVa, DVb, and DVc, and a second electrode of the input transistor T2 may be connected to the first end portions 132a, 132b, and 132c of the storage capacitor Cst and the gate electrode of the driving transistor T1. Data lines 171a, 171b, and 171c may transfer different data voltages DVa, DVb, and DVc, respectively, and the input transistor T2 of respective pixels PXa, PXb, and PXc may be connected to different data lines 171a, 171b, and 171c. The gate electrode of the input transistor T2 of the respective pixels PXa, PXb, and PXc may be connected to same first scan signal line 151 to receive the first scan signal SC of a same timing. In case that the input transistor T2 of the respective pixels PXa, PXb, and PXc are simultaneously turned on by the first scan signal SC of the same timing, different data voltages DVa, DVb, and DVc may be transferred through different data lines 171a, 171b, and 171c to the gate electrode of the driving transistor T1 of the respective pixels PXa, PXb, and PXc and the first end portions 132a, 132b, and 132c of the storage capacitor Cst.

The embodiment of FIG. 1 is an embodiment in which the gate electrode of the initializing transistor T3 receives a scan signal different from that of the gate electrode of the input transistor T2.

The gate electrode of the initializing transistor T3 may be connected to a second scan signal line 151-1 transferring a second scan signal SS. The first electrode of the initializing transistor T3 may be connected to the second end portions 125a, 125b, and 125c of the storage capacitor Cst, the second electrode of the driving transistor T1, anodes of the light emitting diodes EDa, EDb, and EDc, the overlapping electrodes BMLa, BMLb, and BMLc, and the first end portions of the light emitting capacitors Cleda, Cledb, and Cledc, and a second electrode of the initializing transistor T3 may be connected to an initializing voltage line 173 transferring an initializing voltage VINT. The initializing transistor T3 may be turned on according to the second scan signal SS and may transfer the initializing voltage VINT to anodes of the light emitting diodes EDa, EDb, and EDc, the first end portions of the light emitting capacitors Cleda, Cledb, and Cledc, the overlapping electrodes BMLa, BMLb, and BMLc, and the second end portions 125a, 125b, and 125c of the storage capacitor Cst to initialize voltages of the anodes of the light emitting diodes EDa, EDb, and EDc.

The initializing voltage line 173 may function as a sensing wiring SL by performing an operation of sensing the voltages of the anodes of the light emitting diodes EDa, EDb, and EDc before applying the initializing voltage VINT. By the sensing operation, it may be confirmed whether the voltage of the anode is maintained at the target voltage. The sensing operation and the initializing operation of transmitting the initializing voltage VINT may be proceeded by being temporally separated, and the initializing operation may be performed after the sensing operation is performed.

In the embodiment of FIG. 1, the turn-on period of the initializing transistor T3 and the input transistor T2 may be distinguished, such that the write operation performed by the input transistor T2 and the initializing operation performed by the initializing transistor T3 (and/or sensing operation) may be performed at different timings.

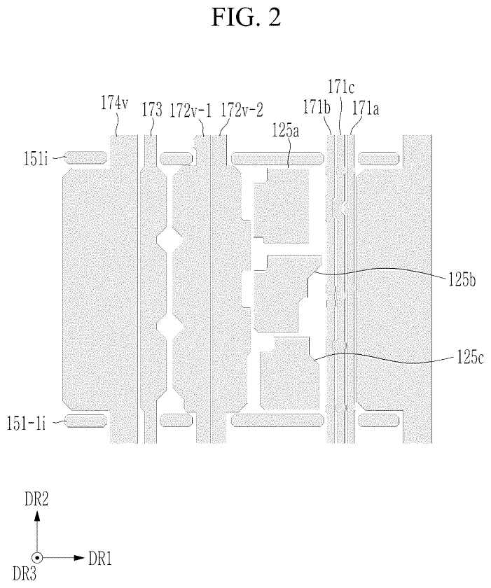

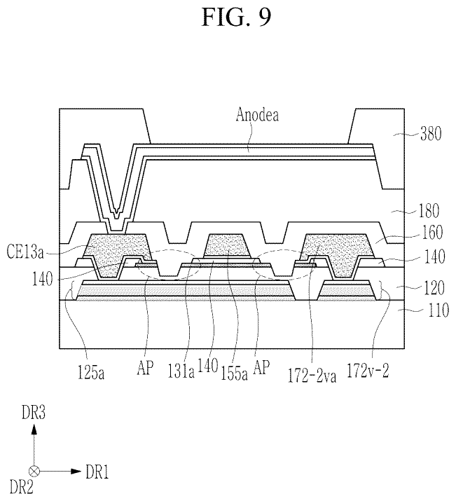

The first end portions 132a, 132b, and 132c of the storage capacitor Cst may be connected to the gate electrode of the driving transistor T1 and the second electrode of the input transistor T2, and the second end portions 125a, 125b, and 125c may be connected to the first electrode of the initializing transistor T3, the second electrode of the driving transistor T1, the overlapping electrodes BMLa, BMLb, and BMLc, the anodes of the light emitting diodes EDa, EDb, and EDc and the first end portions of the light emitting capacitors Cleda, Cledb, and Cledc. In FIG. 1, reference numerals are shown at the first end portions 132a, 132b, and 132c and the second end portions 125a, 125b, and 125c of the storage capacitor Cst, which is to clearly indicate which part in FIG. 2 and the like corresponds to the storage capacitor Cst. For example, the first end portions 132a, 132b, and 132c of the storage capacitor Cst may be electrically connected to the gate electrode of the driving transistor T1, and the second end portions 125a, 125b, and 125c of the storage capacitor Cst may be positioned on lower storage electrodes 125a, 125b, and 125c. Referring to FIG. 9, in a cross-sectional structure of the storage capacitor Cst, the lower storage electrodes 125a, 125b, and 125c may be positioned lowermost, and second semiconductors 132a, 132b, and 132c electrically connected to the gate electrode of the driving transistor T1 may be positioned on them being insulated therefrom. A first insulating layer 120 positioned between these two layers may function as a dielectric layer.

Cathodes of the light emitting diodes EDa, EDb, and EDc may receive a driving low voltage ELVSS through a driving low voltage line 174, and the light emitting diodes EDa, EDb, and EDc may display gradation by emitting light according to output current of the driving transistor T1.

For example, light emitting capacitors Cleda, Cledb, and Cledc may be formed at end portions (e.g., opposite end portions) of the light emitting diodes EDa, EDb, and EDc such that the voltage at end portions (e.g., opposite end portions) of the light emitting diodes EDa, EDb, and EDc may be maintained constant. Thus, the light emitting diodes EDa, EDb, and EDc may display constant luminance due to the light emitting capacitors Cleda, Cledb, and Cledc.

Hereinafter, an operation of a pixel having a circuit as shown in FIG. 1 will be described.

In FIG. 1, each of the transistors T1, T2, and T3 may be an N-type transistor, and may be turned on in case that a high-level voltage is applied to the gate electrode. However, according to an embodiment, each of the transistors T1, T2, and T3 may be a P-type transistor.

In case that the emission section end portions, one frame may start. Thereafter, the second scan signal SS with a high level may be supplied to turn on the initializing transistor T3. In case that the initializing transistor T3 is turned on, an initializing operation and/or a sensing operation may be performed.

An embodiment in which both the initializing operation and the sensing operation are performed will be described below.

The sensing operation may be performed before the initializing operation is performed. For example, in case that the initializing transistor T3 is turned on, the initializing voltage line 173 may function as a sensing wiring SL to sense the voltages of the anodes of the light emitting diodes EDa, EDb, and EDc. By the sensing operation, it may be confirmed whether the voltage of the anode is maintained at the target voltage.

Thereafter, the initializing operation may be performed, and the second end portions 125a, 125b, and 125c of the storage capacitor Cst, the second electrode of the driving transistor T1, the overlapping electrodes BMLa, BMLb, and BMLc, and the voltages of the anodes of the light emitting diodes EDa, EDb, and EDc may be changed to the initializing voltage VINT transmitted from the initializing voltage line 173 to perform initialization.

As such, the sensing operation and the initializing operation of transmitting the initializing voltage VINT may be temporally separated, such that the pixel may perform various operations with using a minimum number of transistors and reducing the area occupied by the pixel. As a result, resolution of the display panel may be improved.

Along with the initializing operation or at a separate timing, the first scan signal SC may be also changed to the high level and applied, the input transistor T2 may be turned on, and the write operation may be performed. For example, the data voltages DVa, DVb, and DVc from the data lines 171a, 171b, and 171c through the turned-on input transistor T2 may be applied to and stored in the gate electrode of the driving transistor T1 and the first end portions 132a, 132b, and 132c of the storage capacitor Cst.

By the initializing operation and the write operation, data voltages DVa, DVb, and DVc and the initializing voltage VINT may be respectively applied to end portions (e.g., opposite end portions) of the storage capacitor Cst. In case that the initializing transistor T3 is turned on, in case that the output current is generated in the driving transistor T1, it may be output to the outside through the initializing transistor T3 and the initializing voltage line 173, thereby not being input to the light emitting diodes EDa, EDb, and EDc. For example, according to an embodiment, the driving voltage ELVDD may be applied as a low-level voltage or the driving low voltage ELVSS may be applied as a high-level voltage during the writing period in which the first scan signal SC of the high level may be supplied, such that the current may be prevented from flowing through the light emitting diodes EDa, EDb, and EDc.

Thereafter, in case that the first scan signal SC is changed to the low level, by the high-level driving voltage ELVDD applied to the driving transistor T1 and the gate voltage of the driving transistor T1 stored in the storage capacitor Cst, the driving transistor T1 may generate and output an output current. The output current of the driving transistor T1 may be input to the light emitting diodes EDa, EDb, and EDc, and a light emitting period in which the light emitting diodes EDa, EDb, and EDc emit light proceeds.

Unlike the embodiment of FIG. 1, the gate electrode of the initializing transistor T3 may receive the same scan signal as the gate electrode of the input transistor T2 in some embodiments.

Among the pixels PXa, PXb, and PXc having the same circuit structure as in FIG. 1, the specific structure of the pixel circuit portion will be discussed in detail referring to FIG. 2 to FIG. 10, and a planar structure will be discussed referring to FIG. 2 to FIG. 8.

FIGS. 2, 3, 4, 5, 6, 7, and 8 are schematic plan views showing a pixel of a light emitting display device according to an embodiment according to manufacturing sequence.

FIG. 2 to FIG. 8 show a structure of the pixel circuit portion including the transistors T1, T2, and T3 and the storage capacitor Cst formed on a substrate 110, without showing the anodes of the light emitting diodes EDa, EDb, and EDc and structures thereon.

As shown in FIG. 2 to FIG. 8, each pixel circuit portion may be arranged in a second direction DR2. Referring to FIG. 2, a first pixel circuit portion belonging to the first pixel PXa may be positioned uppermost, a second pixel circuit portion belonging to the second pixel PXb may be position therebelow, and a third pixel circuit portion belonging to the third pixel PXc may be positioned lowermost. Hereinafter, the three pixels PXa, PXb, and PXc are also referred to as a group of pixels.

Referring to FIG. 2, a first conductive layer may be formed on a substrate (refer to 110 in FIG. 9).

The first conductive layer may include the lower storage electrodes 125a, 125b, and 125c, the data lines 171a, 171b, and 171c, first driving voltage lines 172v-1 and 172v-2, the initializing voltage line 173, a first driving low voltage line 174v, an island-type first scan signal line supporting portion 151i, and an island-type second scan signal line supporting portion 151-1i.

Each of the lower storage electrodes 125a, 125b, and 125c may have an island structure, and three lower storage electrodes 125a, 125b, and 125c may be arranged along to a second direction DR2. Respective the lower storage electrodes 125a, 125b, and 125c may have different shapes, and a portion (e.g., a portion overlapping first semiconductors 131a, 131b, and 131c) may be a portion correspond to the overlapping electrodes BMLa, BMLb, and BMLc FIG. 1.

The data lines 171a, 171b, and 171c, the first driving voltage lines 172v-1 and 172v-2, the initializing voltage line 173, and the first driving low voltage line 174v may extend in the second direction DR2.

The data lines 171a, 171b, and 171c may transfer the data voltages DVa, DVb, and DVc, respectively, the first driving voltage lines 172v-1 and 172v-2 may transfer the driving voltage ELVDD. The initializing voltage line 173 may transfer the initializing voltage VINT or perform the sensing operation. For example, the first driving low voltage line 174v may transfer the driving low voltage ELVSS, and may have a portion (e.g., extension portion) with an extended width.

For example, the island-type first scan signal line supporting portion 151i and the island-type second scan signal line supporting portion 151-1i overlap the first scan signal line 151 and the second scan signal line 151-1, respectively, and may have an electrically connected structure.

Referring to FIG. 9, the first insulating layer 120 may be positioned on the first conductive layer.

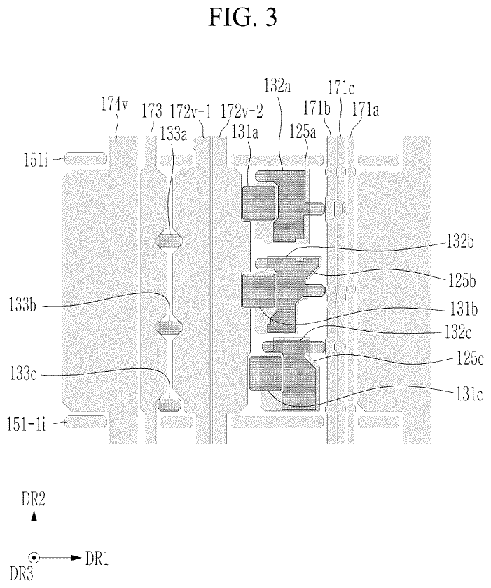

The semiconductor layer as shown in FIG. 3 may be positioned on the first insulating layer 120.

The semiconductor layer may include the first semiconductors 131a, 131b, and 131c, the second semiconductors 132a, 132b, and 132c, and third semiconductors 133a, 133b, and 133c.

The first semiconductors 131a, 131b, and 131c and the second semiconductors 132a, 132b, and 132c may be separated in an island-type form, and have a structure that overlap the lower storage electrodes 125a, 125b, and 125c in a plan view. A portion of the first semiconductors 131a, 131b, and 131c and a portion of the second semiconductors 132a, 132b, and 132c may not overlap the lower storage electrodes 125a, 125b, and 125c in a plan view.

The third semiconductors 133a, 133b, and 133c may be positioned between a first driving voltage line 172v-1 and the initializing voltage line 173 in a plan view, and at least a portion among the third semiconductors 133a, 133b, and 133c may overlap a portion of the first driving voltage line 172v-1 and/or a portion of the initializing voltage line 173 in a plan view.

Referring to FIG. 9, a second insulating layer 140 may be positioned on the semiconductor layer.

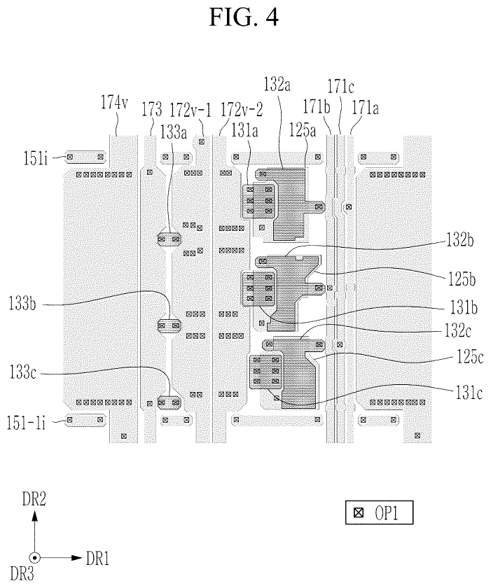

Openings OP1 may be formed in the first insulating layer 120 and the second insulating layer 140 as shown in FIG. 4. An opening OP1 overlapping the semiconductor layer in a plan view may be positioned only in the second insulating layer 140, and the opening OP1 overlapping the first conductive layer in a plan view may be positioned over the first insulating layer 120 and the second insulating layer 140.

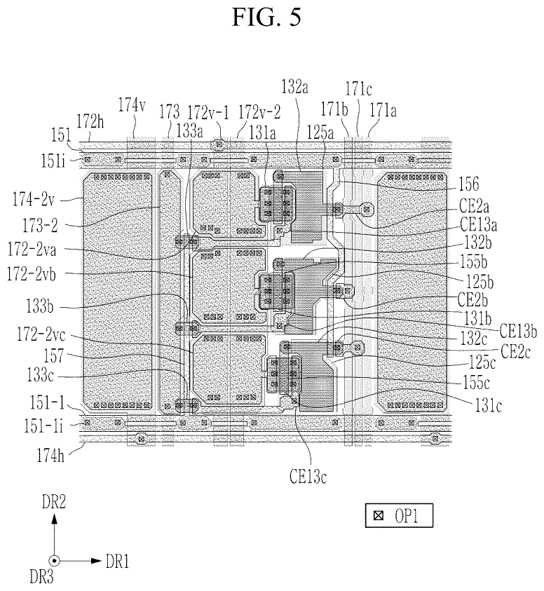

Referring to FIG. 5, a second conductive layer may be formed on the second insulating layer 140 in which the openings OP1 are formed.

The second conductive layer (hereinafter, also referred to as a gate conductive layer) may include gate electrodes 155a, 155b, and 155c of the driving transistors T1 (hereinafter, also referred to as first gate electrodes), a gate electrode 156 (hereinafter, also referred to as a second gate electrode) of the input transistor T2, a gate electrode 157 (hereinafter, also referred to as a third gate electrode) of the initializing transistor T3, the first scan signal line 151, the second scan signal line 151-1, a second driving voltage line 172h, a second driving low voltage line 174h, an island-type driving low voltage line connection portion 174-2v, driving voltage line connection portions 172-2va, 172-2vb, and 172-2vc, an initializing voltage line connection portion 173-2, and connection electrodes CE13a, CE13b, CE13c, CE2a, CE2b, and CE2c.

First gate electrodes 155a, 155b, and 155c may be electrically connected to the second semiconductors 132a, 132b, and 132c through each the opening OP1, and extend the second direction DR2 to overlap the first semiconductors 131a, 131b, and 131c in a plan view.

Each of the first scan signal line 151 and the second scan signal line 151-1 may extend in a first direction DR1, and may include a second gate electrode 156 and a third gate electrode 157 protruding in the second direction DR2. Each of the second gate electrode 156 and the third gate electrode 157 may have a portion overlapping the second semiconductors 132a, 132b, and 132c and the third semiconductors 133a, 133b, and 133c in a plan view. The first scan signal line 151 and the second scan signal line 151-1 may be electrically connected to the island-type first scan signal line supporting portion 151i and the island-type second scan signal line supporting portion 151-1i through each the opening OP1.

The second driving voltage line 172h may transmit the driving voltage ELVDD to the first direction DR1, and electrically connected to at least one among the first driving voltage lines 172v-1 and 172v-2 through the opening OP1.

Driving voltage line connection portions 172-2va, 172-2vb, and 172-2vc may include a protrusion portion overlapping a portion of the first semiconductors 131a, 131b, and 131c, respectively. Driving voltage line connection portions 172-2va, 172-2vb, and 172-2vc may be electrically connected to the first driving voltage lines 172v-1 and 172v-2 and first end portions of the first semiconductors 131a, 131b, and 131c through the opening OP1. As a result, the driving voltage ELVDD may be transferred to the first end portions of the first semiconductors 131a, 131b, and 131c.

The initializing voltage line connection portion 173-2 may be electrically connected to the initializing voltage line 173 and first end portions of the third semiconductors 133a, 133b, and 133c through the opening OP1. As a result, the initializing voltage VINT may be transferred to the first end portions of the third semiconductors 133a, 133b, and 133c, or the voltage or current of the first end portions of the third semiconductors 133a, 133b, and 133c may be sensed or measured.

The second driving low voltage line 174h may transmit the driving low voltage ELVSS to the first direction DR1, and electrically connected to the first driving low voltage line 174v through the opening OP1. For example, the island-type driving low voltage line connection portion 174-2v may be electrically connected to a portion (e.g., extension portion) with an extended width of the first driving low voltage line 174v through the opening OP1.

Connection electrodes CE13a, CE13b, and CE13c may have end portions (e.g., opposite end portions) and central portion, first end portions thereof may be electrically connected to second end portions of the first semiconductors 131a, 131b, and 131c through the opening OP1, second end portions thereof may be electrically connected to second end portions of the third semiconductors 133a, 133b, and 133c through the opening OP1, and central portions thereof may be electrically connected to the lower storage electrodes 125a, 125b, and 125c through the opening OP1.

First end portions of connection electrodes CE2a, CE2b, and CE2c may be electrically connected to the second semiconductors 132a, 132b, and 132c through the opening OP1, and second end portions thereof may be electrically connected to the data lines 171a, 171b, and 171c through the opening OP1.

After the second conductive layer is formed, a doping process may be performed, the semiconductor layer covered by the second conductive layer may not be doped, and the semiconductor layer not covered by the second conductive layer may be doped to have the same or similar characteristics as the conductive layer. As a result, the semiconductor layer and the second conductive layer may be electrically connected through the opening OP1. For example, a portion of the opening OP1 may overlap the semiconductor layer in a plan view, and another portion of the opening OP1 may overlap the second conductive layer in a plan view.

Referring to FIG. 9, a third insulating layer 160 and an organic insulating layer 180 may be positioned on the second conductive layer. In another example, the third insulating layer 160 may be omitted.

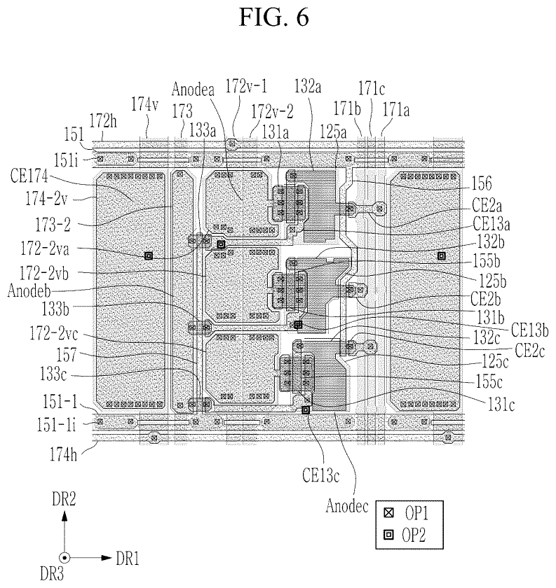

Openings OP2 may be formed in the third insulating layer 160 and the organic insulating layer 180 as shown in FIG. 6, and the openings OP2 overlap the connection electrodes CE13a, CE13b, and CE13c and the island-type driving low voltage line connection portion 174-2v in a plan view.

Through the above steps, the structure of the pixel circuit portion except for the light emitting diode may be formed or implemented.

Based on the above structure, the structure and connection relationship of each of the transistors T1, T2, and T3 are described in detail as follows.

The driving transistor T1 may include the first gate electrodes 155a, 155b, and 155c and the first semiconductors 131a, 131b, and 131c, and may have a channel, a first region, and a second region in the first semiconductors 131a, 131b, and 131c. The channel may be formed in the first semiconductors 131a, 131b, and 131c overlapping the first gate electrodes 155a, 155b, and 155c in a plan view, and the first region and the second region have the same or similar conductivity characteristics as a conductor. First regions of the first semiconductors 131a, 131b, and 131c may be electrically connected to the first driving voltage lines 172v-1 and 172v-2 through the opening OP1 and driving voltage line connection portions 172-2va, 172-2vb, and 172-2vc, and may receive the driving voltage ELVDD. For example, second regions of the first semiconductors 131a, 131b, and 131c may be connected to the lower storage electrodes 125a, 125b, and 125c and the second end portions of the third semiconductors 133a, 133b, and 133c through the opening OP1 and the connection electrodes CE13a, CE13b, and CE13c, and electrically connected to a first region of the initializing transistor T3.

The input transistor T2 may include the second gate electrode 156 and the second semiconductors 132a, 132b, and 132c, and may have a channel, a first region, and a second region in the second semiconductors 132a, 132b, and 132c. The channel may be formed in the second semiconductors 132a, 132b, and 132c overlapping the second gate electrode 156 in a plan view, and the first region and the second region have the same or similar conductivity characteristics as a conductor. First regions of the second semiconductors 132a, 132b, and 132c may be electrically connected to the data lines 171a, 171b, and 171c through the opening OP1 and the connection electrodes CE2a, CE2b, and CE2c, and receive the data voltages DVa, DVb, and DVc. For example, second regions of the second semiconductors 132a, 132b, and 132c may be connected to the first gate electrodes 155a, 155b, and 155c through the opening OP1 and electrically connected to the gate electrode of the driving transistor T1. For example, the second regions of the second semiconductors 132a, 132b, and 132c may have widely formed extension portions, and these portions may be also doped to have the same or similar characteristics as a conductor. The extension portion may overlap the lower storage electrodes 125a, 125b, and 125c in a plan view to form the storage capacitor Cst.

The initializing transistor T3 may include the third gate electrode 157 and the third semiconductors 133a, 133b, and 133c, and may have a channel, a first region, and a second region in the third semiconductors 133a, 133b, and 133c. The channel may be formed in the third semiconductors 133a, 133b, and 133c overlapping the third gate electrode 157 in a plan view, and the first region and the second region have the same or similar conductivity characteristics as a conductor. First regions of the third semiconductors 133a, 133b, and 133c may be connected to the lower storage electrodes 125a, 125b, and 125c and the second end portions of the first semiconductors 131a, 131b, and 131c through the opening OP1 and the connection electrodes CE13a, CE13b, and CE13c, and electrically connected to a second region of the driving transistor T1. For example, a second region of the third semiconductors 133a, 133b, and 133c may be connected to the initializing voltage line 173 through the opening OP1 and the initializing voltage line connection portion 173-2, such that the initializing voltage VINT may be transferred or the voltage or current of the first end portions of the third semiconductors 133a, 133b, and 133c may be sensed.

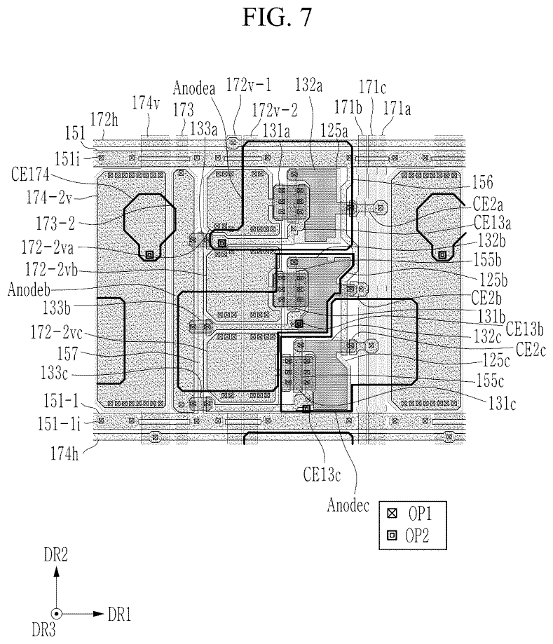

Referring to FIG. 7, an anode conductive layer may be formed on the third insulating layer 160 and the organic insulating layer 180 in which the openings OP2 are formed.

The anode conductive layer may include anodes Anodea, Anodeb, and Anodec and a connection electrode CE174 for a laser drilling process.

The anodes Anodea, Anodeb, and Anodec may be electrically connected to the connection electrodes CE13a, CE13b, and CE13c through an opening OP2, and overlap the first semiconductors 131a, 131b, and 131c and the lower storage electrodes 125a, 125b, and 125c in a plan view.

For example, the connection electrode CE174 for a laser drilling process may be electrically connected to the island-type driving low voltage line connection portion 174-2v through the opening OP2.

Referring to FIG. 9, a pixel defining layer 380 may be positioned on the anode conductive layer.

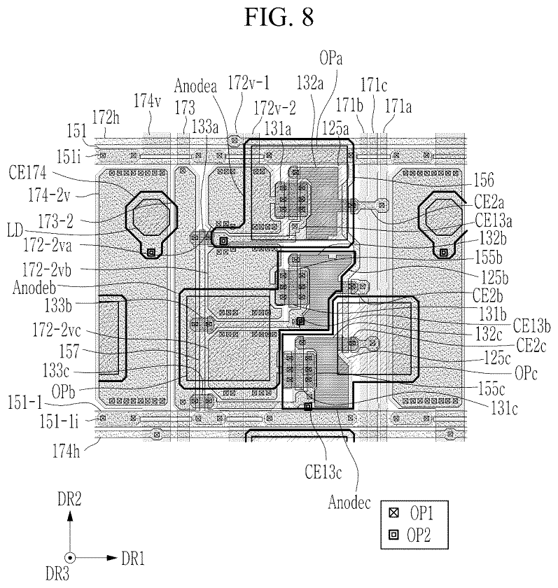

Openings OPa, OPb, and OPc overlapping the anodes Anodea, Anodeb, and Anodec may be formed in the pixel defining layer 380 as shown in FIG. 8. A light emitting layer may be positioned within the opening OPa, OPb, and OPc of the pixel defining layer 380, and a cathode may be positioned on the pixel defining layer 380 and the light emitting layer. The anodes Anodea, Anodeb, and Anodec, the light emitting layer, and cathode may form a light emitting diode. For example, the cathode may be integrally formed over the entire display area.

For example, the pixel defining layer 380 may include a structure in which the light emitting layer and a cathode may be formed, and then a laser may be irradiated to shorten the cathode and the connection electrode CE174 for a laser drilling process. In FIG. 8, the position in which the laser may be irradiated is shown as LD. The pixel defining layer 380 and the light emitting layer may be melted by the laser, and the cathode and the connection electrode CE174 for a laser drilling process may be electrically connected to each other.

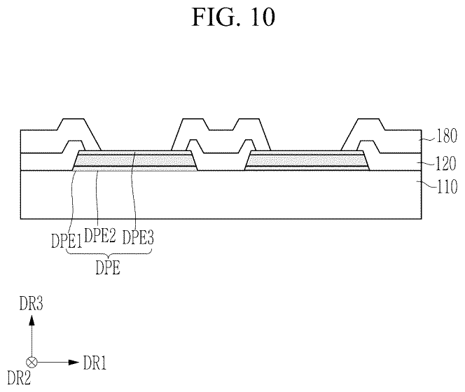

Hereinafter, the cross-sectional structure is discussed with reference to FIG. 9 and FIG. 10, and the cross-sectional structure of the display area will be discussed with reference to FIG. 9.

FIG. 9 is a schematic cross-sectional view of a pixel of a light emitting display device according to an embodiment.

FIG. 9 shows only the cross-sectional structure of the pixel PXa among the three pixels PXa, PXb, and PXc.

A light emitting display device according to an embodiment may include the substrate 110. The substrate 110 may include an insulating material such as glass or plastic and may have flexibility.

The first conductive layer, the first insulating layer 120, the semiconductor layer, the second insulating layer 140, the second conductive layer, the third insulating layer 160 and the organic insulating layer 180 may be sequentially formed on the substrate 110. The anode conductive layer and the pixel defining layer 380 may be positioned on the organic insulating layer 180. For example, the first insulating layer 120, the second insulating layer 140, and the third insulating layer 160 may be inorganic insulating layers including an inorganic insulating material, and the organic insulating layer 180 may be an organic insulating layer including an organic insulating material. For example, the inorganic insulating material may include silicon nitride (SiNₓ), silicon oxide (SiOₓ), and silicon nitride oxide (SiOₓN_{y}), and the like, and the organic insulating material may include polyimide, an acrylic polymer, and a siloxane-based polymer. For example, the first conductive layer and the second conductive layer may include at least one of copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), an alloy thereof. Each of the first conductive layer and the second conductive layer may be formed of a single layer or multiple layers. For example, the semiconductor layer may include a semiconductor material such as amorphous silicon, polycrystalline silicon, or an oxide semiconductor. Hereinafter, an embodiment in which the semiconductor layer is an oxide semiconductor will be discussed.

In FIG. 9, the lower storage electrode 125a and the first driving voltage line 172v-2 are shown in the first conductive layer. The first conductive layer may have a triple layer structure, in which a (1-1)-th conductive layer positioned lowermost may include titanium (Ti), a (1-2)-th conductive layer positioned intermediate may include copper (Cu), a (1-3)-th conductive layer positioned uppermost may include an alloy of molybdenum (Mo) and titanium (Ti). The first conductive layer formed in the triple layer may be etched by two wet etching processes. For example, the (1-3)-th conductive layer may be etched by a first wet etching process, and the (1-1)-th conductive layer and the (1-2)-th conductive layer may be etched by a second wet etching process.

In FIG. 9, a first gate electrode 155a, a driving voltage line connection portion 172-2va, and a connection electrode CE13a are shown in the second conductive layer. The second conductive layer may have a double layer structure, in which a (2-1)-th conductive layer positioned thereunder may include titanium (Ti), and a (2-2)-th conductive layer positioned in an upper portion may include copper (Cu). The second conductive layer formed in the double layer may be etched by a single wet etching process, and the (2-1)-th conductive layer and the (2-2)-th conductive layer may be etched together by a single wet etching process.

In FIG. 9, the first semiconductor 131a is illustrated in the semiconductor layer.

Referring to FIG. 9, the second insulating layer 140 positioned under the second conductive layer and the first insulating layer 120 positioned under the semiconductor layer may be further etched, corresponding to the boundary portion between the second conductive layer and the semiconductor layer, respectively. In FIG. 9, an additionally etched portion AP may be indicated by a dotted line.

For example, after the wet etching process on the second conductive layer, additional dry etching process may be performed such that the exposed second insulating layer 140 and the semiconductor layer exposed by the opening OP1 of the second insulating layer 140 may etched. As a result, like the additionally etched portion AP, the second insulating layer 140, the semiconductor layer and the first insulating layer 120 may be etched.

In an embodiment, the second insulating layer 140 may have the same or similar boundary portion as the second conductive layer, and the first insulating layer 120 may have the same or similar boundary portion as the semiconductor layer.

In FIG. 9, the first insulating layer 120 may not be fully etched but partially etched, such that the first conductive layer thereunder may not be exposed. According to an embodiment, the first insulating layer 120 may not be additionally etched.

For example, the second insulating layer 140 may be etched by using the second conductive layer as a mask, and thereby may be structured to be positioned only under the second conductive layer, and not in other regions.

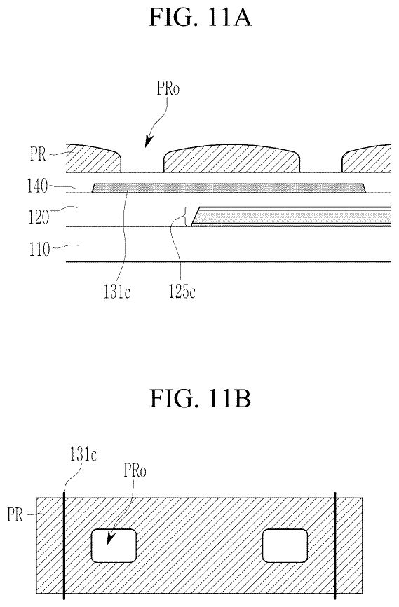

The dry etching process after the wet etching process on the second conductive layer as described above will be described below in more detail with reference to FIGS. 11A, 11B, 12A, 12B, 13A, 13B, 14A, 14B, 15A, and 15B.

The third insulating layer 160 and the organic insulating layer 180 may be sequentially stacked on the second conductive layer. According to an embodiment, the third insulating layer 160 may be omitted.

The anode conductive layer may be positioned on the organic insulating layer 180, and FIG. 9 shows the anode Anodea.

The anode Anodea may be connected to the connection electrode CE13a through opening (refer to OP2 in FIG. 6) positioned on the third insulating layer 160 and the organic insulating layer 180, and the connection electrode CE13a may be connected to the lower storage electrode 125a through the opening (refer to OP1 in FIG. 4) positioned in the second insulating layer 140 and the first insulating layer 120. As a result, the lower storage electrode 125a and the anode Anodea may be electrically connected to each other.

A pixel defining layer 380 having an opening corresponding to the anode may be formed on the anode Anodea. The pixel defining layer 380 may cover a portion of the anode Anodea, and the light emitting layer may be positioned on the anode Anodea exposed through the opening of the pixel defining layer 380. A cathode may be positioned on the light emitting layer and the pixel defining layer 380, and the anode Anodea, the light emitting layer, and cathode may form a light emitting diode.

According to an embodiment, the light emitting layer may be formed only within the opening of the pixel defining layer 380 or may be formed on the pixel defining layer 380.

An encapsulation layer may be positioned above the cathode, and a color conversion layer or color filter may be included on the encapsulation layer.

In the above, a cross-sectional structure of the display area has been discussed referring to FIG. 9. Hereinafter, a cross-sectional structure of the data pad portion will be discussed referring to FIG. 10.

FIG. 10 is a schematic cross-sectional view of a data pad portion of a light emitting display device according to an embodiment.

Data pad portion may include a data pad electrode DPE, and may be disposed exterior to the display area as a portion to receive the data voltages DVa, DVb, and DVc among various signals transferred to the respective pixels PXa, PXb, and PXc disposed in the display area from the outside. The data pad electrode DPE may be electrically connected to the data lines 171a, 171b, and 171c.

For example, other signals transferred to the respective pixels PXa, PXb, and PXc, for example, the first scan signal SC or the second scan signal SS, may be applied by forming a scan driver outside or on a side of the display area. For example, the scan driver may be formed by the same process as the pixels PXa, PXb, and PXc, and may have a structure in which a pad portion for receiving a signal from the outside is not formed.

The data pad electrode DPE of FIG. 10 may be positioned on the substrate 110, and the organic insulating layer 180 may be positioned on the data pad electrode DPE. The organic insulating layer 180 may include an opening exposing a portion of the data pad electrode DPE, and thus the data pad electrode DPE may be exposed.

For example, the first insulating layer 120 and the second insulating layer 140 may be positioned on the data pad electrode DPE like the organic insulating layer 180, and may be formed with an opening exposing the portion of the data pad electrode DPE.

The data pad electrode DPE of FIG. 10 may have a triple layer structure, and include the same material as the first conductive layer of the display area. The data pad electrode DPE of FIG. 10 and the first conductive layer of the display area may be formed by the same process.

For example, in the data pad electrode DPE, the same as in the first conductive layer, a first data pad electrode DPE1 positioned lowermost may include titanium (Ti), a second data pad electrode DPE2 positioned intermediate may include copper (Cu), and a third data pad electrode DPE3 positioned uppermost may include an alloy of molybdenum (Mo) and titanium (Ti). As the data pad electrode DPE is formed in the triple layer, the first data pad electrode DPE1 and the second data pad electrode DPE2 positioned under the third data pad electrode DPE3 may be protected by the third data pad electrode DPE3 positioned uppermost in a process of forming a data pad portion and/or a subsequent process, e.g., in a process of forming the anode conductive layer and/or a subsequent process. According to the embodiment, in case that the third data pad electrode DPE3 is not positioned, the first data pad electrode DPE1 and the second data pad electrode DPE2 may be etched in a subsequent process.

Referring to FIG. 9 and FIG. 10, the first conductive layer and the data pad electrode DPE may include, at its upper portion, a conductive layer including an alloy of molybdenum (Mo) and titanium (Ti) such that the data pad electrode DPE may be protected in subsequent processes.

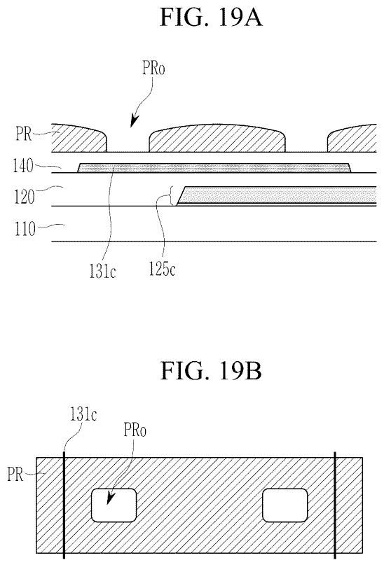

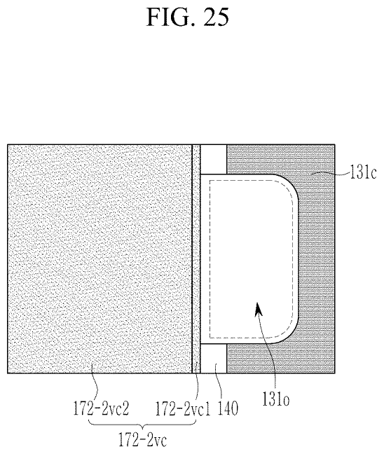

In Comparative Examples (see FIGS. 19A, 19B, 20A, 20B, 21A, 21B, 22, 23A, 23B, 24A, 24B, and 25), the data pad electrodes and the second conductive layer may be formed of the same material and in the same process, but an additional upper conductive layer may be required to protect the data pad electrodes. However, in such a Comparative Example, as shown in FIGS. 19A, 19B, 20A, 20B, 21A, 21B, 22, 23A, 23B, 24A, and 24B, the second conductive layer may be wet-etched twice, and as shown in FIG. 25, a disadvantage may occur in that resistance may increase as the width of the second conductive layer (e.g., gate conductive layer) may be narrowed as the second conductive layer is additionally etched. Comparative Examples will be described below with reference to FIGS. 19A, 19B, 20A, 20B, 21A, 21B, 22, 23A, 23B, 24A, 24B, and 25.

Unlike the Comparative Example, in an embodiment, because the data pad electrode and the first conductive layer is formed of the same material and in the same process, and the second conductive layer may be formed by a single wet etching process, the second conductive layer (e.g., gate conductive layer) having a constant width may be formed.

As described above, in an embodiment, in case of forming the second conductive layer, the wet etching process may be performed once and then additional dry etching process may be performed, in connection to which the structure according to each process will be discussed in detail referring to FIGS. 11A, 11B, 12A, 12B, 13A, 13B, 14A, 14B, 15A, and 15B.

FIGS. 11A, 11B, 12A, 12B, 13A, 13B, 14A, 14B, 15A, and 15B sequentially show a method of manufacturing a gate conductive layer according to an embodiment.

FIGS. 11A, 11B, 12A, 12B, 13A, 13B, 14A, 14B, 15A, and 15B only show only a portion of the display area, and sequentially show structures according to process sequence in which an opening (refer to OP1 in FIG. 4) is form in the second insulating layer 140, the second conductive layer of a double layer is formed at a single wet etching process, and an additional dry etching process is performed, and in each drawing, each of FIGS. 11A, 12A, 13A, 14A, and 15A shows a cross-sectional view, and each of FIGS. 11B, 12B, 13B, 14B, and 15B shows a planar view.

FIGS. 11A and 11B show forming of the opening (refer to OP1 in FIG. 4) in the second insulating layer 140.

Referring to FIG. 11A, the first conductive layer including a lower storage electrode 125c may be formed on the substrate 110, and the first conductive layer may be covered by the first insulating layer 120. The semiconductor layer including a first semiconductor 131c may be positioned on the first insulating layer 120, and the semiconductor layer may be the second insulating layer 140. For example, the first conductive layer may have a triple layer structure, in which a lower layer may include titanium (Ti), intermediate layer may include copper (Cu), and an upper layer may include an alloy of molybdenum (Mo) and titanium (Ti). The first conductive layer having the triple layer structure may be etched by two wet etching processes, in which the upper layer is etched by a first wet etching process, and the intermediate layer and the lower layer are etched by a second wet etching process.

A first photoresist pattern layer PR may be formed in order to form the opening (refer to OP1 in FIG. 4) on the second insulating layer 140. The first photoresist pattern layer PR may include an opening Pro for forming the opening (see OP1 in FIG. 4).

FIG. 11B shows only the first semiconductor 131c which is a semiconductor layer among the plurality of layers and the first photoresist pattern layer PR disposed thereon and including the opening Pro.

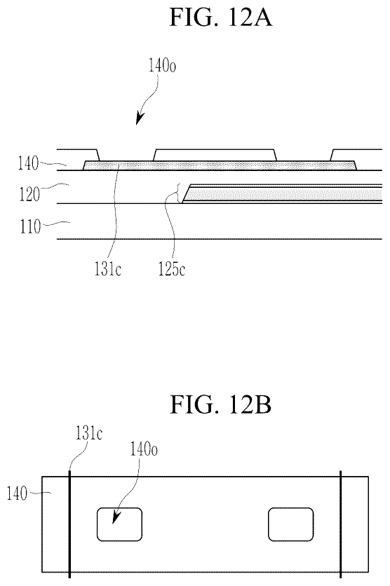

Thereafter, referring to FIGS. 12A and 12B, an opening 140o may be formed in the second insulating layer 140 by a dry etching process by using the first photoresist pattern layer PR. Thereafter, the first photoresist pattern layer PR may be removed by a stripper.

FIG. 12B shows only the first semiconductor 131c which is a semiconductor layer among the plurality of layers and the second insulating layer 140 disposed thereon and including the opening 140o.

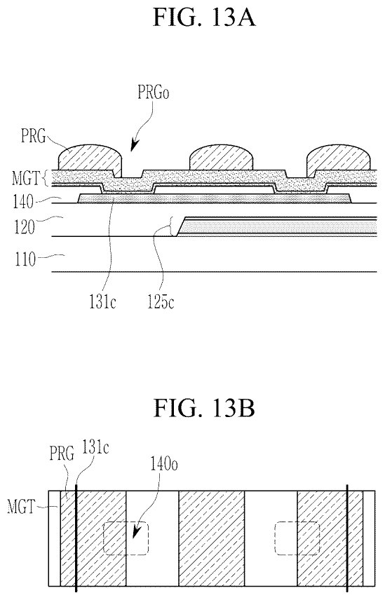

Thereafter, referring to FIGS. 13A and 13B, a second conductor material MGT may be stacked on the second insulating layer 140 having the opening 140o formed therein, and a second photoresist pattern layer PRG may be formed thereon. The second photoresist pattern layer PRG may have an open portion PRGo. Referring to FIG. 13B, the open portion PRGo may be formed to extend in a direction.

For example, the second conductor material MGT may be stacked in a double layer including a lower layer and an upper layer. For example, the lower layer may include titanium (Ti), and the upper layer may include copper (Cu).

FIG. 13B shows a structure in which the second photoresist pattern layer PRG is stacked on the second conductor material MGT, and the opening 140o positioned in the second insulating layer 140 may be covered, so illustrated as a dotted line.

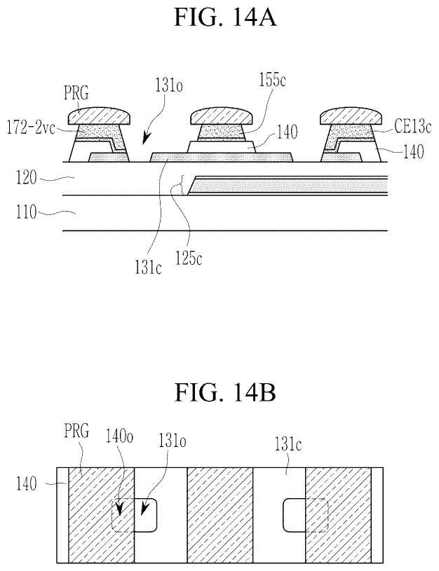

Thereafter, the second conductor material MGT of the double layer may be etched by a single wet etching process as shown in FIGS. 14A and 14B, and the second conductive layer may be formed or implemented.

In more detail, referring to FIGS. 14A and 14B, a driving voltage line connection portion 172-2vc, a first gate electrode 155c, and the connection electrode CE13c may be formed or implemented through a single wet etching process on the second conductor material MGT.

Thereafter, the second insulating layer 140 and the first semiconductor 131c positioned below may be additionally etched by a dry etching process. For example, a portion corresponding to the open portion PRGo of the second photoresist pattern layer PRG may include a portion in which the second insulating layer 140 is positioned and a portion of the second insulating layer 140 in which the opening 140o is positioned, and the first semiconductor 131c is exposed by the opening 140o.

As a result, the second insulating layer 140 exposed by a dry etching process and a part of the first semiconductor 131c exposed by the opening 140o among the second insulating layer 140 may be etched.

Therefore, the first semiconductor 131c may be etched along the shape of the opening 140o, and the second insulating layer 140 may be removed long in a direction like the open portion PRGo of the second photoresist pattern layer PRG. As a result, an opening may be formed in the first semiconductor 131c as indicated by the reference numeral “131o” in FIGS. 14A and 14B.

FIG. 14B shows the second photoresist pattern layer PRG, the exposed first semiconductor 131c, and an opening 131o positioned in the first semiconductor 131c. In FIG. 14B, a dotted line indicates the opening 140o from which the second insulating layer 140 may be removed.

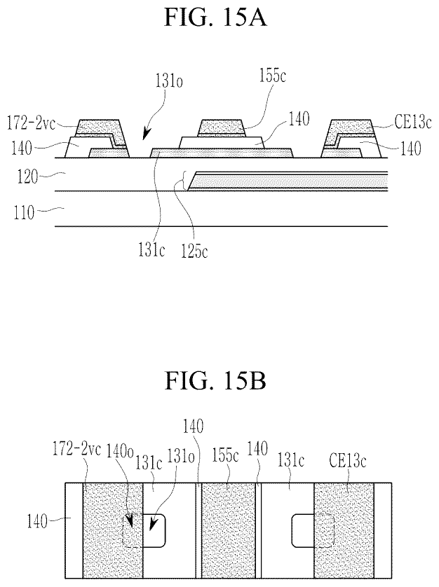

Thereafter, a strip process may be performed, and a structure after the strip process is performed is shown in FIGS. 15A and 15B.

Referring to FIGS. 15A and 15B, a structure in which the second photoresist pattern layer PRG is removed by a stripper is shown.

Referring to FIGS. 14A, 14B, 15A, and 15B, the first insulating layer 120 may not be etched during a dry etching process, but according to an embodiment, the exposed first insulating layer 120 may also be etched during a dry etching process.

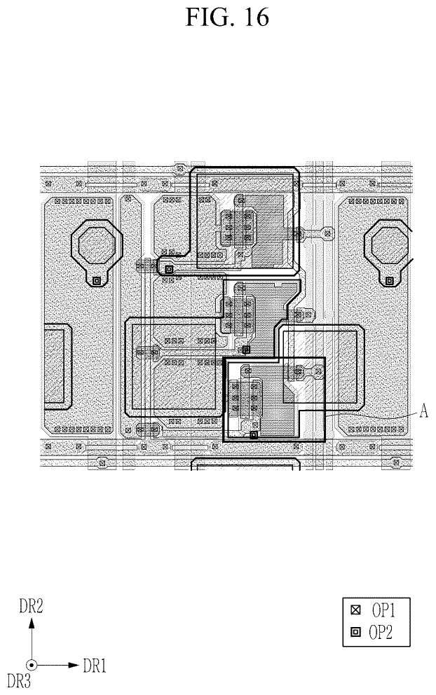

A structure of the display area formed by the above process will be discussed in detail with reference to FIGS. 16, 17, and 18.

FIGS. 16, 17, and 18 show a structure of a portion of a pixel according to an embodiment.

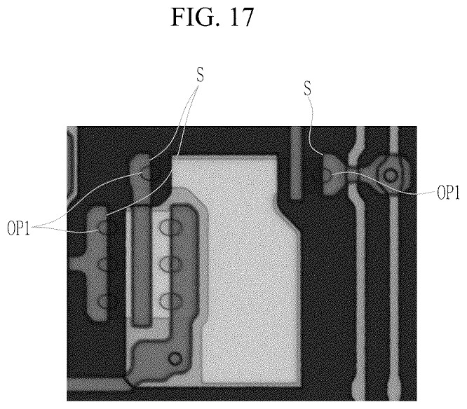

FIG. 16 additionally shows a quadrangular portion A in a drawing corresponding to FIG. 8. A photograph of the rectangular portion A of FIG. 16 corresponds to the structure of FIG. 17.

In FIG. 17, the opening OP1 and a boundary portion S of the second conductive layer positioned around the opening OP1 may be illustrated as the photographed planar image. The boundary portion S of the second conductive layer may be a portion in which an additional etching process is occurred in case that the second conductive layer is wet etched twice as in the Comparative Example, and the difference between Comparative Example and the embodiment may be compared by comparing this portion.

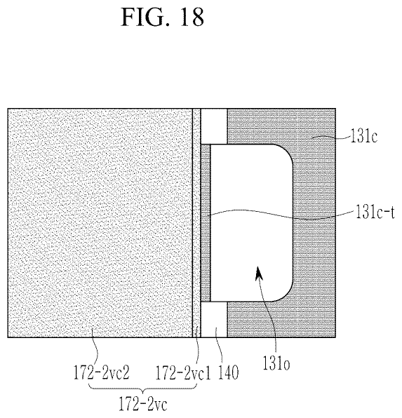

FIG. 18 is an enlarged schematic plan view showing an opening OP1 positioned rightmost among the openings OP1 of FIG. 17 and its peripheral structure.

The detailed structure of FIG. 18 is as follows.

FIG. 18 shows an enlarged schematic view of a portion including the driving voltage line connection portion 172-2vc and the first semiconductor 131c. The driving voltage line connection portion 172-2vc and the first semiconductor 131c may be connected by the opening OP1, a portion of the opening OP1 may be positioned under the driving voltage line connection portion 172-2vc to be covered thereby, and in FIG. 18, in a portion in the opening OP1 that is not covered by the driving voltage line connection portion 172-2vc, the opening 131o may be formed in the first semiconductor 131c as shown in FIGS. 14A, 14B, 15A, and 15B.

The second insulating layer 140 exposed by not being covered by the driving voltage line connection portion 172-2vc and the first semiconductor 131c exposed by the opening OP1 of the second insulating layer 140 may be etched at the time of the dry etching process after the wet etching process by using the photoresist (refer to PRG in FIGS. 13A, 13B, 14A, and 14B) for etching the second conductive layer. As a result, the second insulating layer 140 may be positioned only along the boundary portion of the photoresist (refer to PRG in FIGS. 13A, 13B, 14A, and 14B), and in the opening OP1 of the second insulating layer 140, the opening 131o of the first semiconductor 131c may be formed while the exposed first semiconductor 131c is etched. For example, as shown in FIG. 18, in a portion adjacent to the driving voltage line connection portion 172-2vc, a boundary portion 131c-t of the opening 131o that is not etched by being covered by the photoresist (refer to PRG in FIGS. 13A, 13B, 14A, and 14B) protrudes in the first direction DR1.

In more detail, the driving voltage line connection portion 172-2vc may be formed in a double layer, and may include a first driving voltage line connection portion 172-2vc1 positioned in a lower portion and a second driving voltage line connection portion 172-2vc2 positioned in an upper portion. In the driving voltage line connection portion 172-2vc, due to its tapered side surface, the first driving voltage line connection portion 172-2vc1 may be formed wither the second driving voltage line connection portion 172-2vc2 positioned in an upper portion, and the second driving voltage line connection portion 172-2vc2 may be formed to protrude toward the first semiconductor 131c.

The second insulating layer 140 may be positioned under the driving voltage line connection portion 172-2vc except for the opening OP1, and the second insulating layer 140 may have a width wider than the driving voltage line connection portion 172-2vc, such that, in a plan view, a portion of the second insulating layer 140 may extend to protrude to an outer side of the driving voltage line connection portion 172-2vc. For example, the second insulating layer 140 may protrude from a periphery of the opening OP1 to the outer side of the driving voltage line connection portion 172-2vc in a plan view. The portion of the second insulating layer 140 protruding to the outer side of the driving voltage line connection portion 172-2vc also may include a portion (or opening) 131o in the opening OP1 that is not covered by the driving voltage line connection portion 172-2vc such that the second insulating layer 140 exposed only in sides (e.g., opposite sides) in the second direction DR2 may be positioned.

In such a structure, a periphery of the driving voltage line connection portion 172-2vc may not be additional etched as the driving voltage line connection portion 172-2vc that is the second conductive layer is formed by a single wet etching process, a portion (or opening) 131o in the opening OP1 that is not covered by the driving voltage line connection portion 172-2vc may be formed relatively narrowly. As a result, in the first semiconductor 131c, the boundary portion 131c-t of the opening OP1 positioned at a side of the driving voltage line connection portion 172-2vc may be formed with a sufficient width with protruding from the driving voltage line connection portion 172-2vc in the first direction DR1 in a plan view, and the resistance may not be increased.

In the Comparative Example, as shown in FIG. 25, while being formed relatively widely, the first semiconductor 131c positioned thereunder may be formed narrowly, to have high resistance value. Disadvantages of the Comparative Example will be discussed in detail below referring to FIGS. 19A, 19B, 20A, 20B, 21A, 21B, 22, 23A, 23B, 24A, 24B, and 25.

First, the manufacturing method of the Comparative Example will be described in detail referring to FIGS. 19A, 19B, 20A, 20B, 21A, 21B, 22, 23A, 23B, 24A, and 24B.

FIGS. 19A, 19B, 20A, 20B, 21A, 21B, 22, 23A, 23B, 24A, and 24B sequentially show a method of manufacturing a gate conductive layer according to a Comparative Example.

In the Comparative Example, unlike the embodiment, the first conductive layer may be formed as a double layer, the second conductive layer may be formed as a triple layer, and the data pad electrode may be formed as a second conductive layer that is a triple layer.

In FIGS. 19A, 19B, 20A, 20B, 21A, 21B, 22, 23A, 23B, 24A, and 24B, an opening (refer to OP1 in FIG. 4) may be formed in the second insulating layer 140 in the display area, and the second conductive layer of a double layer may be formed by the two wet etching process, and an additional dry etching process may be performed, and in each drawing, each of FIGS. 19A, 20A, 21A, 23A, and 24A shows a cross-sectional view, and each of FIGS. 19B, 20B, 21B, 23B, and 24B shows a planar view.

FIGS. 19A and 19B show forming of the opening (refer to OP1 in FIG. 4) in the second insulating layer 140.

Referring to FIG. 19A, the first conductive layer including the lower storage electrode 125c may be formed on the substrate 110, and the first conductive layer may be covered by the first insulating layer 120. The semiconductor layer including the first semiconductor 131c may be positioned on the first insulating layer 120, and the semiconductor layer may be the second insulating layer 140. For example, the first conductive layer may have a double layer structure, in which a lower layer may include titanium (Ti), and an upper layer may include copper (Cu). The first conductive layer having the double layer structure may be etched by a single wet etching process.

The first photoresist pattern layer PR may be formed in order to form the opening (refer to OP1 in FIG. 4) on the second insulating layer 140. The first photoresist pattern layer PR may include an opening PRo for forming the opening (see OP1 in FIG. 4).

FIG. 19B shows only the first semiconductor 131c which is a semiconductor layer among the plurality of layers and the first photoresist pattern layer PR disposed thereon and including the opening PRo.

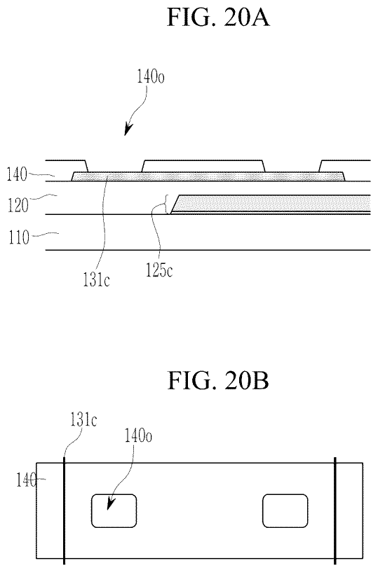

Thereafter, referring to FIGS. 20A and 20B, an opening 140o may be formed in the second insulating layer 140 by a dry etching process by using the first photoresist pattern layer PR. Thereafter, the first photoresist pattern layer PR may be removed by a stripper.

FIG. 20B shows only the first semiconductor 131c which is a semiconductor layer among the plurality of layers and the second insulating layer 140 disposed thereon and including the opening 140o.

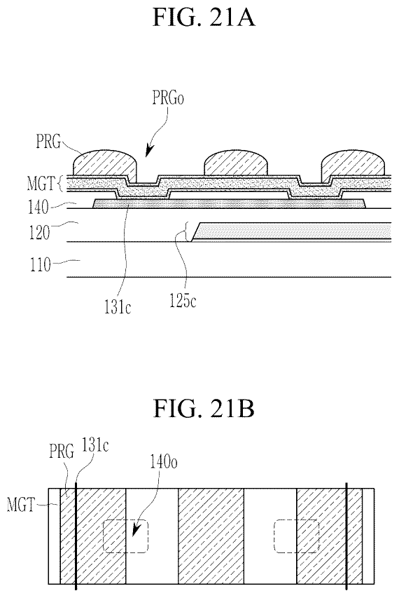

Thereafter, referring to FIGS. 21A and 21B, a second conductor material MGT may be stacked on the second insulating layer 140 having the opening 140o formed therein, and a second photoresist pattern layer PRG may be formed thereon. The second photoresist pattern layer PRG may have the open portion PRGo. Referring to FIG. 21B, the open portion PRGo may be formed to extend in a direction.

For example, the second conductor material MGT may be stacked in a triple layer including a lowermost layer, an intermediate layer, and an uppermost layer. For example, the lowermost layer may include titanium (Ti), the intermediate layer may include copper (Cu), and the uppermost layer may include Indium tin oxide (ITO) that is a transparent conductive material.

FIG. 21B shows a structure in which the second photoresist pattern layer PRG is stacked on the second conductor material MGT, and the opening 140o positioned in the second insulating layer 140 may be covered, so illustrated as a dotted line.

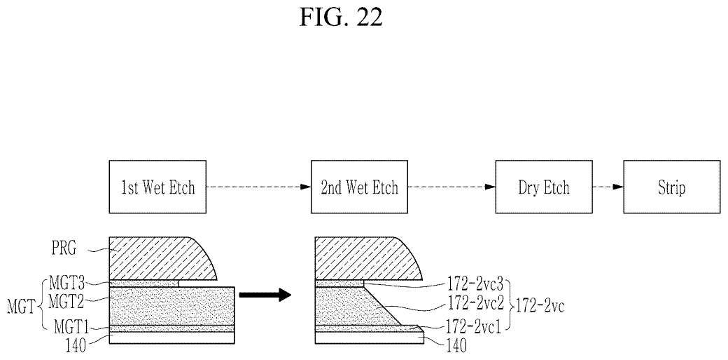

Thereafter, the second conductor material MGT may be etched through a sequence shown in FIG. 22 to form the driving voltage line connection portion 172-2vc, and the surrounding insulating layer may be etched.

In more detail, according to FIG. 22, the second conductive layer and lower insulating layer may be etched by sequentially performing two wet etching processes (i.e., 1^{st} Wet Etch and 2^{nd} Wet Etch), one dry etching process, and a strip process.

A first etchant used in the first wet etching process may etch only an upper layer MGT3 of the second conductor material MGT, but may not etch an intermediate layer MGT2 and a lower layer MGT1.

A second etchant used in the second wet etching process may etch the intermediate layer MGT2 and the lower layer MGT1 of the second conductor material MGT. For example, the upper layer MGT3 of the second conductor material MGT may also be additionally etched to have a non-protruding structure. In case that the second wet etching process is performed, the driving voltage line connection portion 172-2vc having the triple layers 172-2vc1, 172-2vc2, and 172-2vc3 may be formed or implemented.

Thereafter, the second insulating layer 140 and the semiconductor layer positioned below may be additionally etched by a dry etching process, and according to an embodiment, the first insulating layer 120 may also be etched.

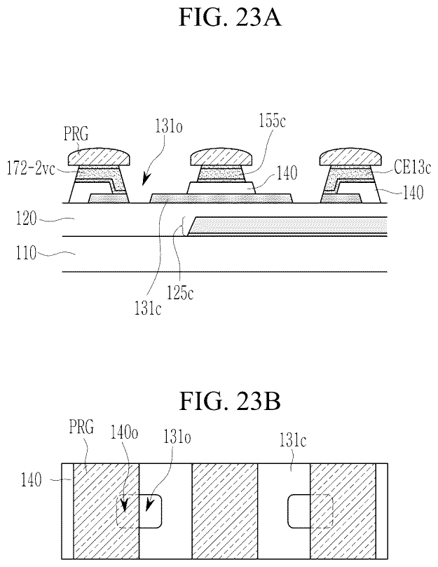

A structure performed up to the dry etching process is shown in FIGS. 23A and 23B.

Referring to FIGS. 23A and 23B, the driving voltage line connection portion 172-2vc, the first gate electrode 155c, and the connection electrode CE13c may be formed or implemented by two wet etching processes (e.g., the first wet etching process and the second wet etching process).

Thereafter, the second insulating layer 140 and the first semiconductor 131c positioned below may be additionally etched by a dry etching process. For example, a portion corresponding to the open portion PRGo of the second photoresist pattern layer PRG may include a portion in which the second insulating layer 140 is positioned and a portion of the second insulating layer 140 in which the opening 140o is positioned, and the first semiconductor 131c is exposed by the opening 140o.

As a result, the second insulating layer 140 exposed by a dry etching process and a part of the first semiconductor 131c exposed by the opening 140o among the second insulating layer 140 may be etched.

Therefore, the first semiconductor 131c may be etched along the shape of the opening 140o, and the second insulating layer 140 may be removed long in a direction like the open portion PRGo of the second photoresist pattern layer PRG. As a result, an opening may be formed in the first semiconductor 131c as indicated by the reference numeral “131o” in FIGS. 23A and 23B.

FIG. 23B shows the second photoresist pattern layer PRG, the exposed first semiconductor 131c, and an opening 131o positioned in the first semiconductor 131c. In FIG. 23B, a dotted line indicates the opening 140o from which the second insulating layer 140 is removed.

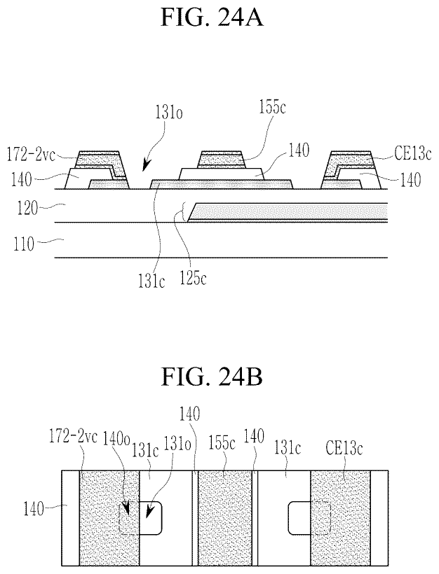

Referring back to FIG. 22, a strip process may be performed after a dry etching process, and a structure after the strip process is performed is shown in FIGS. 24A and 24B.

Referring to FIGS. 24A and 24B, a structure in which the second photoresist pattern layer PRG may be removed by a stripper is shown.

Referring to FIGS. 23A, 23B, 24A, and 24B, the first insulating layer 120 may not be etched during a dry etching process, but according to an embodiment, the exposed first insulating layer 120 may also be etched during a dry etching process.

A structure of the portion corresponding to FIG. 18 in the display area formed as the Comparative Example as described above is shown in FIG. 25.

FIG. 25 shows a structure of a portion of a pixel according to a Comparative Example.

The dotted line shown in FIG. 25 shows the boundary portion of the opening 131o of the first semiconductor 131c of FIG. 18. It may be seen that the boundary portion of the opening 131o of the first semiconductor 131c shown in FIG. 25 of the Comparative Example is relatively large. Referring to FIG. 18, although the boundary portion 131c-t adjacent to the driving voltage line connection portion 172-2vc among boundaries of the opening 131o of the first semiconductor 131c protrudes in the first direction DR1, in the Comparative Example of FIG. 25, it is shown that the boundary portion adjacent to the driving voltage line connection portion 172-2vc among boundaries of the opening 131o of the first semiconductor 131c may not protrude. As a result, the width of the first semiconductor 131c may be formed to be relatively narrow, and the first semiconductor 131c may have a relatively high resistance value.

For example, according to Comparative Example, in case that the second photoresist pattern layer PRG having the same size is formed by two wet etching processes (i.e., 1st Wet Etch and 2nd Wet Etch), the driving voltage line connection portion 172-2vc, the first gate electrode 155c, and the connection electrode CE13c included in the second conductive layer may be relatively further etched, to form a narrower width. In case that a dry etching process is performed by using the second conductive layer formed as a result as a mask, the area of the part to be dry etched may be relatively increased, and the width of the semiconductor layer remaining after being etched is decreased, resulting in increased resistance.

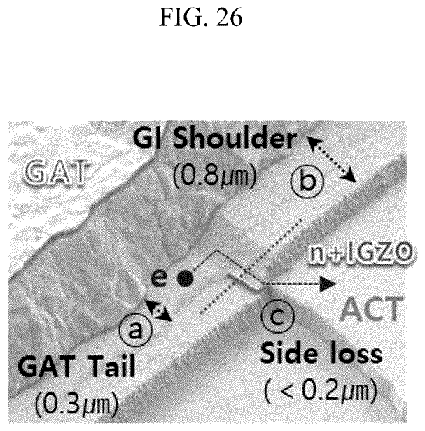

Hereinafter, a drawing photographing the structure of the embodiment will be discussed referring to FIG. 26.

FIG. 26 is an enlarged photographed view of a portion of a pixel according to an exemplary embodiment.

In FIG. 26, a portion of the boundary portion 131c-t of the opening 131o of the first semiconductor 131c of FIG. 18 is enlarged and photographed, and a comparison between FIG. 26 and FIG. 18 is as follows.

In FIG. 26, GAT denotes the driving voltage line connecting portion 172-2vc of the second conductive layer, ACT denotes the first semiconductor 131c of the semiconductor layer, n+IGZO denotes that the semiconductor layer is an n-type oxide semiconductor, and GI Shoulder represents the second insulating layer 140. GAT Tail represents a protruding portion of the first driving voltage line connection portion 172-2vc1 positioned under the driving voltage line connection portion 172-2vc. In FIG. 26, \textcircled{a} represents the protruding width of the first driving voltage line connection portion 172-2vc1, and \textcircled{b} represents the protruding width of the second insulating layer 140. In FIG. 26, the part protruding more than the width \textcircled{a} of the GAT Tail may correspond to the boundary portion 131c-t of the first semiconductor 131c, and the opening 131o of the first semiconductor 131c may be positioned adjacent thereto.

In FIG. 26, \textcircled{c} represents the width that is removed by the dry etching process, and its width being narrower than 0.2 μm may be narrower than the width \textcircled{a} of the GAT Tail, and the boundary portion 131c-t of the first semiconductor 131c may not be etched into the lower portion of the driving voltage line connection portion 172-2vc. As a result, the resistance value may not increase because the width of the first semiconductor 131c is not formed narrowly.

In the above, an embodiment in which the second conductive layer is formed as a double layer and etched together with a single wet etching process has been described.

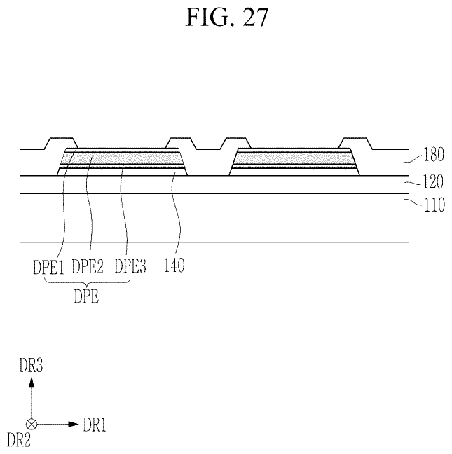

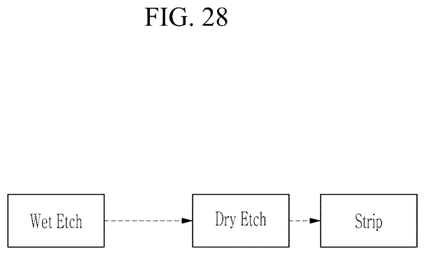

However, according to an embodiment, in case that the second conductive layer is formed as a triple layer, the triple layer may be formed by a single wet etching process in case that a suitable etchant is used, and the second conductive layer may not be over-etched thereby, and such embodiment is discussed referring to FIG. 27 and FIG. 28.

In FIG. 27, a structure of a data pad portion different from that of FIG. 10 will be described.

FIG. 27 is a schematic cross-sectional view of a data pad portion of a light emitting display device according to another example.

In the data pad portion according to the embodiment of FIG. 27, the data pad electrode DPE may include the same material and is formed by the same process, as the second conductive layer.

The data pad electrode DPE of FIG. 27 may be positioned on the substrate 110, the first insulating layer 120, and the second insulating layer 140, and may have a triple layer structure.

In the embodiment of FIG. 27, the substrate 110 and the first insulating layer 120 may be positioned over the entire region, but the second insulating layer 140 may be positioned only under the data pad electrode DPE. The organic insulating layer 180 may be positioned on the data pad electrode DPE, and the organic insulating layer 180 may include an opening exposing the portion of the data pad electrode DPE, and thus the data pad electrode DPE may be exposed.

In the data pad electrode DPE of FIG. 27, the same as in the second conductive layer, the first data pad electrode DPE1 positioned lowermost may include titanium (Ti), the second data pad electrode DPE2 positioned intermediate may include copper (Cu), and the third data pad electrode DPE3 positioned uppermost may include indium tin oxide (ITO) that is a transparent conductive material. As the data pad electrode DPE is formed in the triple layer, the first data pad electrode DPE1 and the second data pad electrode DPE2 positioned in the lower portion may be protected by the third data pad electrode DPE3 positioned uppermost in a process of forming a data pad portion and/or a subsequent process, e.g., in a process of forming the anode conductive layer and/or a subsequent process. According to the embodiment, in case that the third data pad electrode DPE3 is not positioned, the first data pad electrode DPE1 and the second data pad electrode DPE2 may be etched in a subsequent process.

For example, in the embodiment of FIG. 27, the first conductive layer may have a double layer structure, in which a layer positioned in a lower portion may include titanium (Ti), and layer positioned in an upper portion may include copper (Cu).

For example, the data pad electrode DPE of the triple layer may be formed by a single wet etching process as the embodiment of FIG. 28, and a process sequence of etching the second conductive layer will be discussed in FIG. 28.

FIG. 28 shows a method of manufacturing a portion of a light emitting display device according to an embodiment.

Compared to FIG. 22, in FIG. 28, a wet etching process may be performed only once to etch the second conductive layer.

In the embodiment of FIG. 28, unlike FIG. 22, the second conductive layer of the triple layer may be etched together by using a separate etchant. Thereafter, sequentially performing a dry etching process and stripping processes may be the same as in the Comparative Example of FIG. 22, and accordingly, the second insulating layer 140 and the first semiconductor 131c may be additionally formed to form the opening 131o in the first semiconductor 131c. For example, according to an embodiment, the exposed first insulating layer 120 may also be etched during a dry etching process.

In the embodiment of FIG. 28, unlike the Comparative Example of FIG. 22, in an embodiment, since the second conductive layer of the triple layer is formed by a single wet etching process, the second conductive layer (gate conductive layer) having a constant width may be formed, and during a dry etching process, the width of the semiconductor layer positioned thereunder not formed to be relatively narrow. As a result, the resistance value of the semiconductor layer may not increase.

The contents described in FIG. 1 to FIG. 18 except for the contents described above may be equally applied to the embodiments of FIG. 27 and FIG. 28.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A light emitting display device comprising:
a substrate;
a first conductive layer disposed on the substrate;
a first insulating layer covering the first conductive layer;
a semiconductor layer disposed on the first insulating layer;
a second insulating layer disposed on the semiconductor layer;
a second conductive layer disposed on the second insulating layer; and
a data pad electrode disposed in an outer side of a display area, wherein
the first conductive layer is formed as a triple layer including a lower layer, an intermediate layer, and an upper layer,
the data pad electrode and the first conductive layer may be formed as the same triple layer,
the lower layer of the triple layer includes titanium,
the intermediate layer of the triple layer includes copper, and
the upper layer of the triple layer includes an alloy of molybdenum and titanium.

2. The light emitting display device of claim 1, wherein the data pad electrode and the first conductive layer are etched by two wet etching processes.

3. The light emitting display device of claim 1, wherein the second conductive layer is etched by a wet etching process.

4. The light emitting display device of claim 3, wherein the second insulating layer and the semiconductor layer are etched by a dry etching process after the wet etching process.

5. The light emitting display device of claim 4, wherein the first insulating layer is etched by the dry etching process.

6. The light emitting display device of claim 4, wherein:
the first conductive layer includes a lower storage electrode, a data line, and a first driving voltage line,
the semiconductor layer includes a first semiconductor, a second semiconductor, and a third semiconductor, and
the second conductive layer includes a first gate electrode, a first scan signal line, a second scan signal line, and a driving voltage line connection portion.

7. The light emitting display device of claim 6, wherein:
an opening overlapping the first semiconductor is disposed in the second insulating layer,
a first part of the opening does not overlap the second conductive layer in a plan view,
a second part of the opening overlaps the second conductive layer in a plan view, and
in the first semiconductor, the opening is formed by etching a portion of the opening exposed by the first part of the opening by the dry etching process.

8. The light emitting display device of claim 7, wherein the second conductive layer overlapping the opening in a plan view is the driving voltage line connection portion.

9. The light emitting display device of claim 8, wherein the second insulating layer protrudes from a periphery of the opening to an outer side of the driving voltage line connection portion in a plan view.

10. The light emitting display device of claim 9, wherein a boundary portion disposed toward the driving voltage line connection portion among boundary portions of the opening of the first semiconductor protrudes from the driving voltage line connection portion in a plan view.

11. The light emitting display device of claim 3, wherein the second conductive layer is formed as a double layer including a lower layer and an upper layer.

12. The light emitting display device of claim 11, wherein
the lower layer of the double layer includes titanium, and
the upper layer of the double layer includes copper.

13. The light emitting display device of claim 6, further comprising:
an organic insulating layer covering the second conductive layer;
an anode disposed on the organic insulating layer; and
a pixel defining layer including an opening that exposes a portion of the anode.

14. The light emitting display device of claim 13, wherein:
the second conductive layer further comprises a connection electrode electrically connected to the first semiconductor, the third semiconductor, and the lower storage electrode, and
the connection electrode is electrically connected to the anode through the opening disposed on the organic insulating layer.

15. The light emitting display device of claim 13, wherein:
the data pad electrode is disposed on the substrate, and
the organic insulating layer is disposed on the data pad electrode, and comprises an opening exposing a portion of the data pad electrode.

16. The light emitting display device of claim 4, wherein the semiconductor layer comprises an oxide semiconductor.

17. A light emitting display device comprising:
a substrate;
a first conductive layer disposed on the substrate;
a first insulating layer covering the first conductive layer;
a semiconductor layer disposed on the first insulating layer;
a second insulating layer disposed on the semiconductor layer;
a second conductive layer disposed on the second insulating layer; and
a data pad electrode disposed in an outer side of a display area, wherein
the second conductive layer is formed as a triple layer including a lower layer, an intermediate layer, and an upper layer,
the data pad electrode and the second conductive layer are formed as the same triple layer,
the lower layer of the triple layer includes titanium,
the intermediate layer of the triple layer includes copper,
the upper layer of the triple layer includes Indium tin oxide that is a transparent conductive material, and
the data pad electrode and the second conductive layer are formed by a wet etching process.

18. The light emitting display device of claim 17, further comprising:
an organic insulating layer covering the second conductive layer, wherein
the data pad electrode is disposed on the substrate, the first insulating layer, and the second insulating layer, and
the organic insulating layer comprises an opening disposed on the data pad electrode and exposing a portion of the data pad electrode.

19. The light emitting display device of claim 18, wherein the second insulating layer and the semiconductor layer are etched by a dry etching process after the wet etching process.

20. The light emitting display device of claim 19, wherein:
the first conductive layer is formed as a double layer including a lower layer and an upper layer,
the lower layer of the double layer includes titanium, and
the upper layer of the double layer includes copper.
